(19) United States
(12) Patent Application Publication
(10) Pub. No.: US 2020/0176311 A1
(43) Pub. Date: Jun. 4, 2020

(54) ARRANGEMENT METHOD AND ARRANGEMENT STRUCTURE OF CONDUCTIVE MATERIAL, AND LED DISPLAY THEREOF

(71) Applicant: ASTI GLOBAL INC., TAIWAN, CHANGHUA COUNTY (TW)

(72) Inventor: CHIEN-SHOU LIAO, NEW TAIPEI CITY (TW)

(21) Appl. No.: 16/424,883

(22) Filed: May 29, 2019

(30) Foreign Application Priority Data
Nov. 30, 2018 (TW) 107143015

(51) Int. Cl. H01L 21/768; H01L 33/50; H01L 51/50; H01L 23/31; H01L 23/498; H01L 23/00

(52) U.S. Cl. CPC H01L 21/76885; H01L 33/504; H01L 51/50; H01L 24/81; H01L 23/49816; H01L 23/49838; H01L 23/3128

(57) ABSTRACT

An arrangement method of conductive material, and an LED display thereof are provided. The arrangement method of conductive material includes: providing a substrate with an upper surface having a non-solder pad area and a plurality of solder pad areas; forming a conductive layer on the upper surface of the substrate to cover the non-solder pad area and the plurality of solder pad areas; heating the conductive material to melt the conductive material; and dividing the molten conductive material into the plurality of solder pad areas to respectively form a plurality of conductors.

This application claims the benefit of priority to Taiwan Patent Application No. 107143015, filed on Nov. 30, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an arrangement method and arrangement structure, and more particularly to an arrangement method and arrangement structure of conductive material, and LED display thereof.

### BACKGROUND OF THE DISCLOSURE

Solder is an alloy of low melting point and is commonly used to join metal parts. For example, in flip chip technology, solder balls are first formed on the substrate, so that wafers can then be disposed on the solder balls.

In the related art, the solder ball is arranged by being instantaneously and partially heated through high-voltage discharge, so that the solder exposed from a capillary tip is melted into a liquid state. At this time, the molten solder forms a sphere under the effect of surface tension. The capillary is then pressed down onto the solder pad to deform the solder. Atomic diffusion on the contact surface of the solder and the solder pad is promoted, so as to produce a solder joint. A solder ball is formed after the solder is cooled and solidified. Then, each of the solder balls can be respectively aligned with a wafer, and after pressure contact, reflow, and filling of the insulating glue, the wafer package can be completed. Through the use of solder, the integrated circuit on the substrate can be electrically connected to the wafer.

However, the method of arranging the solder balls in the related art has a limitation on the number of the solder balls. The number of the solder balls that may be arranged at a time depends on the number of the capillary, and the solder balls cannot be arranged simultaneously or in large number. Therefore, the method of arranging the solder balls in the related art still leaves room for improvement.

### SUMMARY OF THE DISCLOSURE

In response to the above-referenced technical inadequacies, the present disclosure provides an arrangement method and arrangement structure of conductive material, and LED display thereof.

In one aspect, the present disclosure provides an arrangement method of conductive material including: providing a substrate with an upper surface having a non-solder pad area and a plurality of solder pad areas; forming a conductive material on the upper surface of the substrate to cover the non-solder pad area and the plurality of solder pad areas; heating and melting the conductive material; and dividing the molten conductive material into a plurality of conductors that respectively remain on the solder pad areas.

In one aspect, the present disclosure provides an arrangement structure of conductive material including a substrate and a plurality of conductors. An upper surface of the substrate has multiple solder pad areas. The conductors are respectively disposed on the plurality of solder pad areas. A cohesive force of the conductor in a molten state is greater than an adhesion between the conductor in a molten state and a non-solder pad area of the substrate.

In one aspect, the present disclosure provides an LED display, including a substrate, a plurality of conductors, and a plurality of LED light-emitting elements. An upper surface of the substrate has multiple solder pad areas. The conductors are respectively disposed on the plurality of solder pad areas. Each of the LED light-emitting elements is disposed on the corresponding two conductors. A cohesive force of the conductor in the molten state is greater than an adhesion between the conductor in a molten state and a non-solder pad area of the substrate.

Therefore, one of the beneficial effects of the present disclosure is that, the arrangement method and arrangement structure of conductive material, and LED display thereof has the technical feature of “an upper surface of the substrate having a non-solder pad area and a plurality of solder pad areas”, “heating and melting the conductive material” and “the molten conductive material being divided into a plurality of conductors that respectively remain on the solder pad areas,” so as to allow simultaneous arrangement of a plurality of conductors, thus simplifying the process and reducing process time.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a flow chart of an arrangement method of conductive material of the present disclosure.

FIG. 2 is a schematic perspective view of step S100 of the arrangement method of conductive material of the present disclosure.

FIG. 3 is a side cross-sectional view of the step S100 of the arrangement method of conductive material of the present disclosure.

FIG. 4 is a side cross-sectional view of step S102 of the arrangement method of conductive material of the present disclosure.

FIG. 5 is a side cross-sectional view of step S104 according to one embodiment of the arrangement method of conductive material of the present disclosure.

FIG. 6 is a side cross-sectional view of the step S104 according to another embodiment of the arrangement method of conductive material of the present disclosure.

FIG. 7 is a side cross-sectional view of step S106 of the arrangement method of conductive material of the present disclosure.

FIG. 8 is a side cross-sectional view of step S108 of the arrangement method of conductive material of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

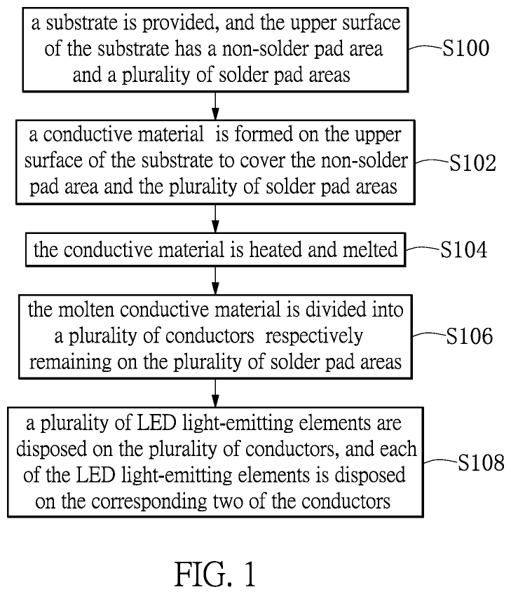

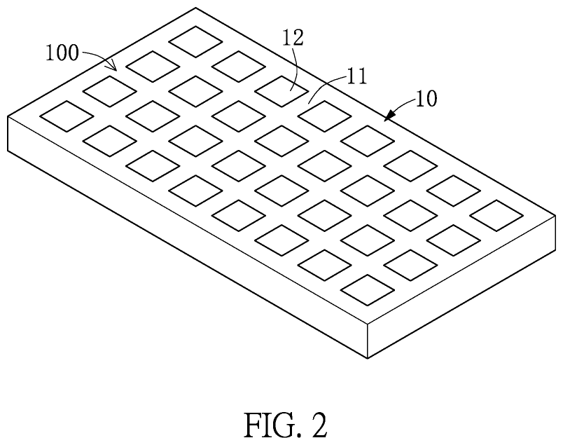

Referring to FIG. 1 to FIG. 3, a first embodiment of the present disclosure provides an arrangement method of conductive material, including the following steps:

Firstly, a substrate 10 is provided, and the upper surface 100 of the substrate 10 has a non-solder pad area 11 and a plurality of solder pad areas 12 (step S100).

The substrate 10 may be a silicon substrate, a sapphire substrate or a substrate of any material.

The material of the non-solder pad area 11 may be the same as or different from the material of the substrate 10. The non-solder pad area 11 may be a continuous non-solder pad area or a non-continuous non-solder pad area. In this embodiment, the material of the non-solder pad area 11 is the same as that of the substrate 10, and the non-solder pad area 11 is a continuous non-solder pad area, but the present disclosure is not limited thereto. In other embodiments, the non-solder pad area 11 may also be composed of a plurality of non-continuous solder pad areas. In this embodiment, the non-solder pad area 11 may be a solder mask (S/M), and the solder mask may be an insulating layer over the substrate 10. For example, the main material of the solder mask can be resin, which can protect the copper foil circuit and avoid soldering the wrong parts, and the solder mask can also be moisture-proof, solder-proof, heat-resistant, and meet requirements in connection with insulation and aesthetics. However, the present disclosure is not limited thereto.

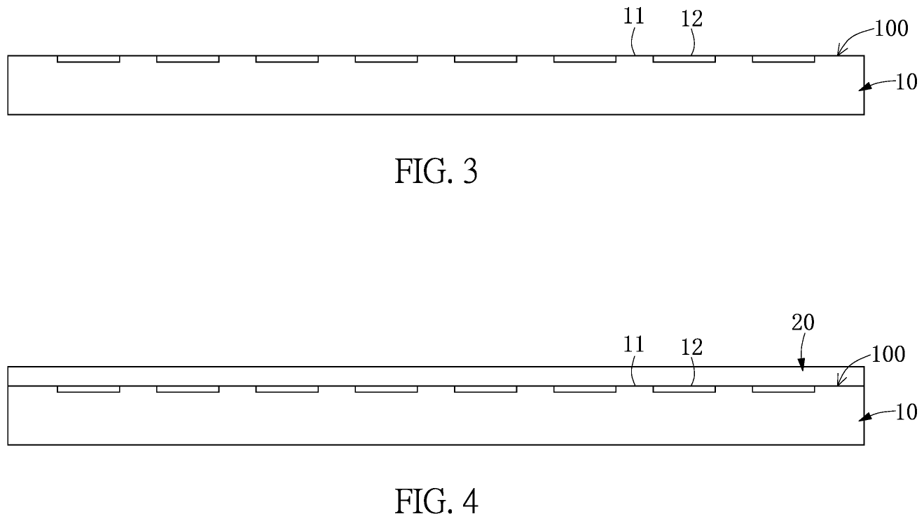

The material of the solder pad area 12 may be metal. For example, the material of the solder pad area 12 may be aluminum, gold, or other metals or alloys. As shown in FIG. 3, the plurality of solder pad areas 12 are independent from and not connected to each other, and any two adjacent solder pad areas 12 are separated by a non-solder pad area 11. The solder pad area 12 is flush with the upper surface 100 of the substrate 10. In other embodiments, the solder pad area 12 may also be higher or lower than the upper surface 100 of the substrate 10.

Next, referring to FIG. 1 and FIG. 4, a conductive material 20 is formed on the upper surface 100 of the substrate 10 to cover the non-solder pad area 11 and the plurality of solder pad areas 12 (step S102). To be specific, the conductive material 20 may be tin, lead, silver, antimony, copper, iron, gold, platinum, indium, nickel, or an alloy including at least two of the above-mentioned metals. Since the materials of the conductive material 20 and the solder pad area 12 are both metals, the adhesion between the conductive material 20 and the solder pad area 12 is greater than the adhesion between the conductive material 20 and the non-solder pad area 11.

Specifically, the step S102 further includes: forming a conductive material 20 on the upper surface 100 of the substrate 10 by printing or coating to cover the plurality of solder pad areas 12. In other embodiments, the conductive material 20 on the upper surface 100 of the substrate 10 can be formed by one or more times of printing coating.

In the present embodiment, the conductive material 20 covers not only the plurality of solder pad areas 12 but also the non-solder pad area 11. That is, the conductive material 20 completely covers the entire upper surface 100 of the substrate 10. In other embodiments, the conductive material 20 may selectively cover all or part of the plurality of solder pad regions 12, and the conductive material 20 may selectively cover all or part of the non-solder pad area 11.

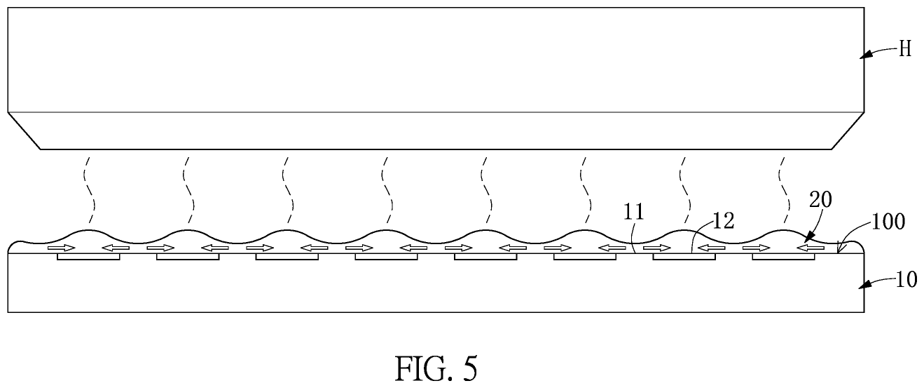

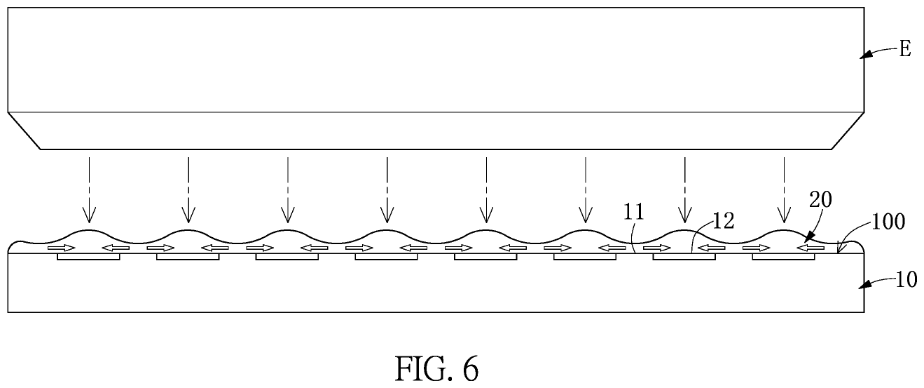

Referring to FIG. 1, FIG. 5, and FIG. 6, the conductive material 20 is heated and melted (step S104). Specifically, step S104 further includes: heating so as to melt the conductive material 20 by a heater H (as shown in FIG. 5). Alternatively, the conductive material 20 is heated and melted by a laser light source E (as shown in FIG. 6). That is, the conductive material 20 can be heated and melted by a heater or laser scanning, but the present disclosure is not limited thereto.

In general, metal has a larger surface energy than non-metal materials. Therefore, when the conductive material 20 is heated into a molten state so as to be flowable, the exposed surface area of the metal tends to decrease in order to reduce the surface energy generated by the bare metal.

In this embodiment, the conductive material 20 and the plurality of solder pad areas 12 are all metal materials, and the material of the non-solder pad area 11 is non-metal. Therefore, in order to reduce the surface energy, the conductive material 20 in a molten state tends to contract and form into a spherical body (i.e., by a cohesive force) with a smaller surface area to reduce the surface area of the conductive material 20. Further, the conductive material 20 in a molten state tends to cover the solder pad area 12 and tends to expose the non-solder pad area 11 to reduce the surface energy generated by the exposed metal.

In short, under the cohesive force of the conductive material 20, the adhesion between the conductive material 20 and the non-solder pad area 11, and the adhesion between the conductive material 20 and the solder pad area 12, the molten conductive material 20 tends to move from the non-solder pad area 11 to the solder pad area 12, so that the conductive material 20 completely covers the solder pad area 12 and exposes the non-solder pad area 11, and forms a sphere over the solder pad area 12.

However, the present disclosure is not limited to the above description. When the material of the non-solder pad area 11 is different from the material of the solder pad area 12, as long as the cohesive force of the conductive material 20 in the molten state is greater than that of the conductive material 20 in the molten state on the non-solder pad area 11, the conductive material 20 in the molten state can be moved from the non-solder pad area 11 to the solder pad area 12.

In this embodiment, any two adjacent solder pad areas 12 are separated by a non-solder pad area 11. Therefore, after being heated into a molten state, the conductive material 20 is spontaneously divided into a plurality of conductors 21 respectively disposed above the plurality of solder pad areas 12 according to the arrangement of the non-solder pad area 11 and the plurality of solder pad areas 12.

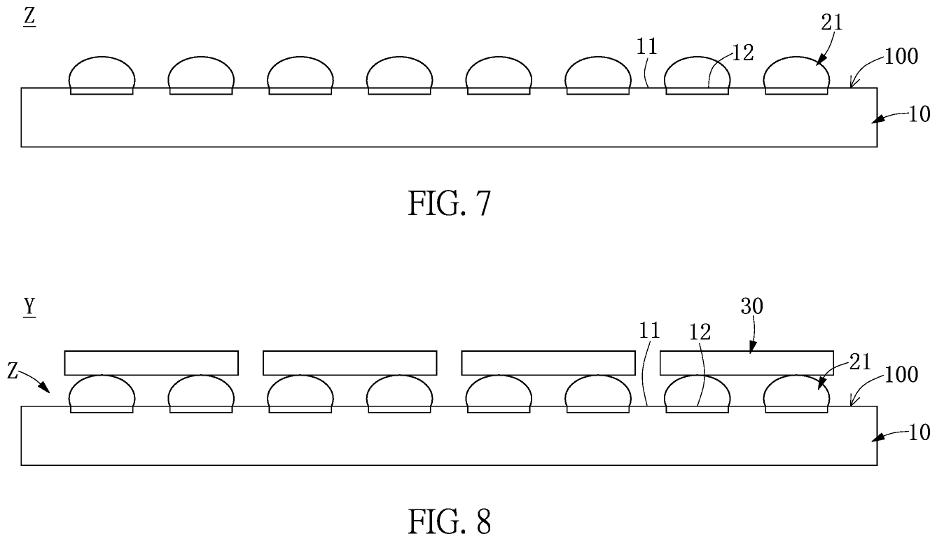

Referring to FIG. 5 to FIG. 7, when the conductive material 20 is in a molten state, the conductive material 20 above the non-solder pad area 11 may move toward the adjacent solder pad area 12 due to the cohesive force, so that the thickness of the conductive material 20 on the non-solder pad area 11 is gradually thinned (as shown in FIG. 5 and FIG. 6). Finally, the conductive material 20 above the non-solder pad area 11 will all move to the adjacent solder pad area 12, so that the non-solder pad area 11 is exposed, and the conductive material 20 above each solder pad area 12 will form a sphere. After the conductive material 20 is cooled and solidified, a conductor 21 is formed above each solder pad area 12 (as shown in FIG. 7).

Referring to FIG. 1 and FIG. 7, the molten conductive material 20 is divided into a plurality of conductors 21 that respectively remain on the plurality of solder pad areas 12 (step S106). Accordingly, according to the above-mentioned arrangement method of the conductive material, the arrangement structure of conductive material Z as shown in FIG. 7 can be completed. In this embodiment, the conductor 21 may be a solder ball.

It should be noted that a different conductive material 20 can be selected depending on the component to be joined. Solder balls can be divided into five categories: ordinary solder balls (atomic percentage of tin is 2 to 100, melting point ranges from 180° C. to 316° C.), low-temperature solder balls (including antimony or indium, melting point ranges from 95° C. to 135° C.), high-temperature solder balls (melting point ranges 186° C. to 309° C.), fatigue-resistant high-purity solder balls (melting point ranges 178° C. and 183° C.) and lead-free solder balls (atomic percentage of lead is less than 0.1).

Referring to FIG. 1 and FIG. 8, a plurality of LED light-emitting elements 30 are disposed on the plurality of conductors 21, and each of the LED light-emitting elements 30 is disposed on the corresponding two of the conductors 21 (step S108). Specifically, a plurality of LED light-emitting elements 30 can be disposed on the plurality of conductors 21 by flip chip technology to complete the LED display Y shown in FIG. 7. However, the present disclosure is not limited thereto.

In conclusion, one of the beneficial effects of the present disclosure is that, the arrangement method and arrangement structure of conductive material, and led display thereof provided by the present disclosure has the technical feature of “the inclusion of the non-solder pad area and the plurality of solder pad areas”, “heating and melting the conductive material” and “dividing the conductive material into a plurality of conductors respectively remaining on the solder pad areas”, so as to so as to simultaneously arrange a plurality of conductors, thus simplifying the process and reducing process time.

Further, by the technical feature of “the conductive material moves from the non-solder pad area to the solder pad area since a cohesive force of the conductive material is greater than the adhesion between the conductive material and a non-solder pad area of the substrate” or “the cohesion of the conductor in the molten state is greater than the adhesion between the conductor and the non-solder pad area of the substrate in the molten state” so that the material is spontaneously divided into a plurality of solder pad areas and forms a plurality of conductors, thus overcoming the process defect that only one conductor could be arranged, and that the capillary needed to be moved over another solder pad area in order to arrange another conductor.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An arrangement method of conductive material, comprising:
providing a substrate with an upper surface having a non-solder pad area and a plurality of solder pad areas;
forming a conductive material on the upper surface of the substrate to cover the non-solder pad area and the solder pad area;
heating and melting the conductive material; and
dividing the molten conductive material into a plurality of conductors that respectively remain on the solder pad areas.

2. The arrangement method of conductive material according to claim 1, wherein the non-solder pad area is a solder mask.

3. The arrangement method of conductive material according to claim 1, wherein a cohesive force of the molten conductive material is greater than an adhesion between the molten conductive material and the non-solder pad area, so that the molten conductive material moves from the non-solder pad area to the solder pad area.

4. The arrangement method of conductive material according to claim 1, wherein the conductive material is formed by printing or coating to form an upper surface of the substrate.

5. The arrangement method of conductive material according to claim 1, wherein the conductive material is melted through heating by a heater or scanning by laser light.

6. An arrangement structure of conductive material, comprising:
a substrate with an upper surface having a plurality of solder pad areas; and
a plurality of conductors respectively disposed on the solder pad areas;
wherein a cohesive force of the conductor in the molten state is greater than the adhesion between the conductor in a molten state and a non-solder pad area of the substrate.

7. The arrangement structure of conductive material according to claim 6, wherein the conductor is a solder ball.

8. The arrangement structure of conductive material according to claim 6, wherein the non-solder pad area is a solder mask.

9. An LED display, comprising:
a substrate with an upper surface having a plurality of solder pad areas;
a plurality of conductors respectively disposed on the plurality of solder pad areas; and
a plurality of LED light-emitting elements, each of the LED light-emitting elements being disposed on the two corresponding conductors;
wherein a cohesive force of the conductor in the molten state is greater than the adhesion between the conductor in a molten state and a non-solder pad area of the substrate.

10. The LED display according to claim 9, wherein the non-solder pad area is a solder mask.
